(19) United States
(12) Patent Application Publication
(10) Pub. No.: US 2024/0401202 A1
(43) Pub. Date: Dec. 5, 2024

(54) BALANCING GAS FLOW TO MULTIPLE STATIONS USING HEATERS UPSTREAM OF FLOW RESTRICTORS

(71) Applicant: LAM RESEARCH CORPORATION, Fremont, CA (US)

(72) Inventors: Brian RATLIFF, Hilsboro, OR (US); Rohit ODE, Portland, OR (US); Stephen TOPPING, Portland, OR (US); Brian Joseph WILLIAMS, Tigard, OR (US); Rigel Martin BRUENING, Sherwood, OR (US)

(21) Appl. No.: 18/693,298

(22) PCT Filed: Sep. 15, 2022
(86) PCT No.: PCT/US2022/043573

§ 371 Date: Mar. 19, 2024

Related U.S. Application Data
(60) Provisional application No. 63/246,656, filed on Sep. 21, 2021.

(51) Int. Cl. C23C 16/52; C23C 16/455

(52) U.S. Cl. CPC C23C 16/52; C23C 16/45536; C23C 16/45561

(57) ABSTRACT

A system for supplying a gas to a plurality of stations of a substrate processing tool includes a gas source to supply the gas, a mass flow controller connected to the gas source, a plurality of conduits, and a plurality of heaters. The conduits are interconnected to each other and are in fluid communication with each other. The conduits include an inlet connected to the mass flow controller, a plurality of portions including a plurality of outlets, and a plurality of gas flow restrictors. The outlets are connected to respective manifolds to supply the gas to the stations. The gas flow restrictors are arranged in the respective portions of the plurality of conduits proximate to the outlets. The heaters are coupled to the respective portions of the conduits that are proximate to the outlets and that include the gas flow restrictors.

### CROSS-REFERENCE TO RELATED APPLICATIONS

This application claims the benefit of U.S. Provisional Application No. 63/246,656, filed on Sep. 21, 2021. The entire disclosure of the application referenced above is incorporated herein by reference.

### FIELD

The present disclosure relates generally to substrate processing systems and more particularly to balancing gas flow to multiple stations using heaters upstream of flow restrictors.

### BACKGROUND

The background description provided here is for the purpose of generally presenting the context of the disclosure. Work of the presently named Applicants, to the extent it is described in this background section, as well as aspects of the description that may not otherwise qualify as prior art at the time of filing, are neither expressly nor impliedly admitted as prior art against the present disclosure.

A substrate processing system typically comprises a plurality of stations (also called processing chambers or process modules) that perform deposition, etching, and other treatments on substrates such as semiconductor wafers. Examples of processes that may be performed on a substrate comprises a chemical vapor deposition (CVD) process, a chemically enhanced plasma vapor deposition (CEPVD) process, a plasma enhanced chemical vapor deposition (PECVD) process, a sputtering physical vapor deposition (PVD) process, atomic layer deposition (ALD), and plasma enhanced ALD (PEALD). Additional examples of processes that may be performed on a substrate comprise, but are not limited to, etching (e.g., chemical etching, plasma etching, reactive ion etching, atomic layer etching (ALE), plasma enhanced ALE (PEALE), etc.) and cleaning processes.

During processing, a substrate is arranged on a substrate support such as a pedestal in a station. During deposition, gas mixtures comprising one or more precursors are introduced into the station, and plasma may be optionally struck to activate chemical reactions. During etching, gas mixtures comprising etch gases are introduced into the station, and plasma may be optionally struck to activate chemical reactions. A computer-controlled robot typically transfers substrates from one station to another in a sequence in which the substrates are to be processed.

Atomic Layer Deposition (ALD) is a thin-film deposition method that sequentially performs a gaseous chemical process to deposit a thin film on a surface of a material (e.g., a surface of a substrate such as a semiconductor wafer). Most ALD reactions use at least two chemicals called precursors (reactants) that react with the surface of the material one precursor at a time in a sequential, self-limiting manner. Through repeated exposure to separate precursors, a thin film is gradually deposited on the surface of the material. Thermal ALD (T-ALD) is carried out in a heated processing chamber. The processing chamber is maintained at a sub-atmospheric pressure using a vacuum pump and a controlled flow of an inert gas. The substrate to be coated with an ALD film is placed in the processing chamber and is allowed to equilibrate with the temperature of the processing chamber before starting the ALD process. Atomic layer etching comprises a sequence alternating between self-limiting chemical modification steps that affect only top atomic layers of a substrate and etching steps that remove only the chemically-modified areas from the substrate. The sequence allows removal of individual atomic layers from the substrate.

### SUMMARY

A system for supplying a gas to a plurality of stations of a substrate processing tool comprises a gas source, a mass flow controller, a plurality of conduits, and a plurality of heaters. The gas source is configured to supply the gas. The mass flow controller is connected to the gas source. The plurality of conduits is interconnected to each other and is in fluid communication with each other. The plurality of conduits comprises an inlet, a plurality of portions, and a plurality of gas flow restrictors. The inlet is connected to the mass flow controller. The plurality of portions comprises a plurality of outlets. The plurality of outlets is connected to a plurality of manifolds to supply the gas to the plurality of stations of the substrate processing tool, respectively. The plurality of gas flow restrictors is arranged in the plurality of portions of the plurality of conduits proximate to the plurality of outlets, respectively. The plurality of heaters is coupled to the plurality of portions of the plurality of conduits, respectively. The plurality of portions to which the plurality of heaters is coupled is proximate to the plurality of outlets and comprises the plurality of gas flow restrictors.

In additional features, the plurality of heaters is arranged coaxially around the plurality of portions of the plurality of conduits, respectively.

In additional features, the plurality of heaters surround the plurality of portions of the plurality of conduits, respectively.

In additional features, the plurality of heaters extend to the plurality of outlets, respectively.

In additional features, inner portions of the plurality of heaters are adjacent to and in thermal communication with the plurality of portions of the plurality of conduits. Outer portions of the plurality of heaters comprise a layer of a thermally insulating material.

In additional features, the system further comprises a controller to supply power to the plurality of heaters to balance flow of the gas through the plurality of outlets.

In additional features, the controller is configured to control the power supplied to each of the plurality of heaters to balance the flow of the gas through the plurality of outlets.

In additional features, the controller is configured to adjust the power supplied to at least one of the plurality of heaters in response to the flow of the gas through one of the plurality of outlets being different than the flow of the gas through others of the plurality of outlets.

In additional features, the controller is configured to receive data from a component of the substrate processing tool located downstream of one of the outlets. The data is indicative of the flow of the gas through one of the plurality of outlets being different than the flow of the gas through others of the plurality of outlets. The controller is configured to adjust the power supplied to at least one of the plurality of heaters based on the data to balance the flow of the gas through the plurality of outlets.

In additional features, the component comprises a sensor associated with one of the stations receiving the gas from the one of the plurality of outlets.

In additional features, the component comprises a metrology system.

In additional features, at least two of the plurality of conduits are interconnected at an angle other than a right angle.

In other features, a method for balancing gas flow to a plurality of stations of a substrate processing tool comprises receiving a gas from a gas source. The method comprises interconnecting a plurality of conduits to comprise an inlet to receive the gas and a plurality of outlets in a plurality of portions of the plurality of conduits, respectively. The method comprises controlling the gas flow through the plurality of conduits using a mass flow controller connected to the inlet. The method comprises restricting the gas flow through the plurality of portions of the plurality of conduits proximate to the plurality of outlets. The method comprises heating the plurality of portions of the plurality of conduits proximate to the plurality of outlets, respectively. The method comprises balancing the gas flow through the plurality of outlets based on the restricting and the heating. The method comprises supplying the gas from the plurality of outlets through a plurality of manifolds connected to the plurality of outlets and to the plurality of stations of the substrate processing tool, respectively.

In additional features, the method further comprises thermally insulating the heated portions of the plurality of conduits.

In additional features, the method further comprises adjusting the heating of one of the plurality of portions in response to the gas flow through one of the plurality of outlets associated with the one of the plurality of portions being different than the gas flow through others of the plurality of outlets.

In additional features, the method further comprises controlling the heating of the plurality of portions based on data received from a component of the substrate processing tool located downstream of one of the outlets to balance the gas flow through the plurality of outlets.

In additional features, the method further comprises controlling the heating of the plurality of portions based on data received from a metrology system to balance the gas flow through the plurality of outlets.

In additional features, the method further comprises interconnecting at least two of the plurality of conduits at an angle other than a right angle.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system (tool) employing a heating system of the present disclosure;

FIG. 2 shows an example of a station used in the tool of FIG. 1 for performing an atomic layer deposition (ALD) process on a substrate;

FIG. 3 shows an example of a station used in the tool of FIG. 1 for performing plasma enhanced chemical vapor deposition (PECVD) process on a substrate;

FIG. 4 shows an example of a heating system used to balance gas flow to the stations of the tool of FIG. 1;

FIG. 5 shows an example of a gas flow restrictor used with the heating system of FIG. 4;

FIG. 6 shows a cross-section of a segment of a gas weldment comprising a heater of the heating system of FIG. 4;

FIG. 7 schematically shows an example of a gas weldment supplying a gas to stations of a tool without using the heating system of the present disclosure; and

FIG. 8 shows a method of balancing gas flow to the stations of the tool of FIG. 1 using the heating system of the present disclosure.

In the drawings, reference numbers may be reused to identify similar and/or identical elements.

### DETAILED DESCRIPTION

According to the present disclosure, in substrate processing tools comprising multiple stations, station-to-station flow balancing of process gases can be achieved on a fine scale using controlled heaters on each leg of gas distribution. The controlled heaters on each leg of gas distribution can be used in combination with a calibrated gas flow restrictor. The flow balancing achieved using separately heated branches of the gas distribution upstream of a system of matched, calibrated, and choked gas flow restrictors is substantially linear. The flow balancing can be performed as an initial tool setup. The flow balancing can be calibrated prior to running a process in the stations. The flow balancing can also be combined with feedback received from sensors in the stations. The flow balancing can also be combined with feedback received from an in-situ metrology system about substrates processed in the stations. The flow balancing combined with the feedback can be used as an active control knob for adjusting a process while the tool is running.

A core advantage of using multi-station tools is that using multiple (e.g., more than two) stations in a tool allows for higher throughput and longer times between station cleaning as compared to tools that use a single station or dual stations. However, one of the basic challenges with the multi-station tools is to balance the gas flow between the multiple stations to promote station-to-station process matching.

Gas flow to showerheads in multiple stations is achieved by receiving gases from a gasbox manifold and then branching out the gas distribution into flow paths to the multiple stations with matched pressure in the flow paths. Thus, a single mass flow controller (MFC) can control the gas flow, which is distributed and split evenly to the multiple stations. The main challenge in such a multi-station system is that the flow balancing is controlled only via manufacturing tolerances of the gasline weldments and gas flow restrictors. The gas flow restrictors are interposed between the ends of the gas weldments and point-of-use valve manifolds (PVMs) that feed the respective showerheads in each station. This type of system cannot be tested prior to delivery to a customer. Flow imbalance which deviates from or is not compliant with process specifications can only be adjusted by laborious cycles of changing hardware and re-testing.

Current tools use a system of choked restrictors to promote flow balancing, limiting flow imbalance to within 5% of process specifications. However, newer processes are much more sensitive to flow balance than before, rendering the current system of choked resistors and the 5% variation obsolete. The system can be supplemented by adding a control knob that controls the heaters on each leg of the gas flow distribution. The control knob can be adjusted at tool startup to provide a fine tune control for flow balancing. The control knob provides the tool with an active control over the flow balancing between the stations.

Specifically, a heating system of the present disclosure provides a flow balancing control knob by heating gases in individual legs of the gas distribution separately. The control knob heats the gases prior to flowing the heated gases through a calibrated gas flow restrictor and a PVM into the showerhead. The mass flow through the gas flow restrictor has an approximately linear relationship to the gas temperature of the gas heated upstream of the gas flow restrictor. The approximately linear relationship holds for any gas which adheres to the Ideal Gas Law. Sensitivity of the heating system (e.g., ˜2% mass flow change for 50° C. temperature difference) allows fine control. While the gas flow restrictors achieve flow balance within 5%, the heating system in conjunction with the gas flow restrictors can increase the sensitivity to well within 1%.

In the heating system of the present disclosure, heaters are placed on the gas distribution branches leading to the showerhead with choked restrictors located at the outlets of the gas distribution branches. N heater zones, one for each of N stations, where N is an integer greater than 1, are used to fine tune the station-to-station flow balance. The N heater zones comprise the gas distribution branches with the respective choked restrictors and heaters. The flow balancing, which comprises individually adjusting power supplied to the heaters using a system controller, is performed during tool startup. The temperature setpoint for each heater can be maintained until the next preventive maintenance (PM) cycle. The flow control knob (i.e., power supply to the heaters) can be used in a wide-ranging manner. The flow control knob can be used along with feedback from sensors and/or the in-situ metrology system. The flow control knob along with the feedback can be used to actively modulate tool performance. The tool performance can be modulated to adapt as the process drifts over time and as deposition accumulation in the stations increases over time.

The heating system improves the linearity with which the flow control is achieved in the stations. Without the feedback, the gas flow can be adjusted by simply flowing the gases at a constant mass flow rate through a single station and adjusting the temperature of the affected leg of the gas distribution to reach a calibrated upstream pressure. The temperature setting for each heater can also be performed during manufacturing prior to shipping the tool, which can simplify subsequent tool setup on site.

Notably, the gas flow is heated upstream of the choked restrictor. Heating the gas upstream of the choked restrictor increases predictability of the system response to temperature changes. Changing the temperature of the gas flow provides a fine adjustment knob. The choked restrictor functions as a coarse control knob that is fixed in the hardware of the system while the heating system functions as a fine control knob. The coarse and fine tuning facility provided by the combination of the choked restrictors and the controllable heaters simplifies the tool startup process on site.

Currently, without the heating system, the choked restrictors are not sufficient to control station-to-station flow balancing within process specifications. The only recourse is to shut down the tool and change hardware of the gas distribution, hoping that the replacement part is at a different end of the specification range. This approach increases system cost and downtime. Instead, with the active fine control knob provided by the heating system, the process of station-to-station flow balancing can be proceduralized. The station-to-station flow balancing can be performed at any point of the tool's life—from manufacturing to setup to runtime. These and other features of the present disclosure are now described in further detail.

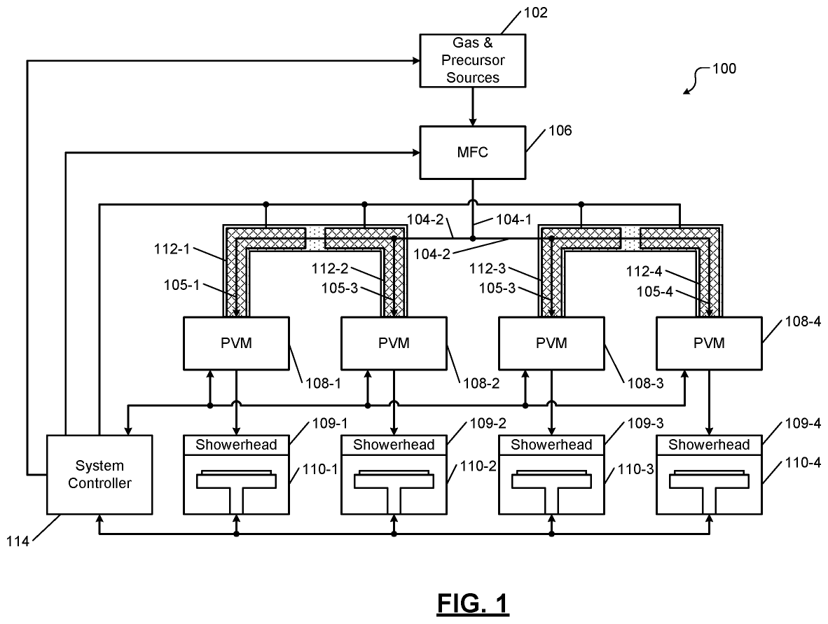

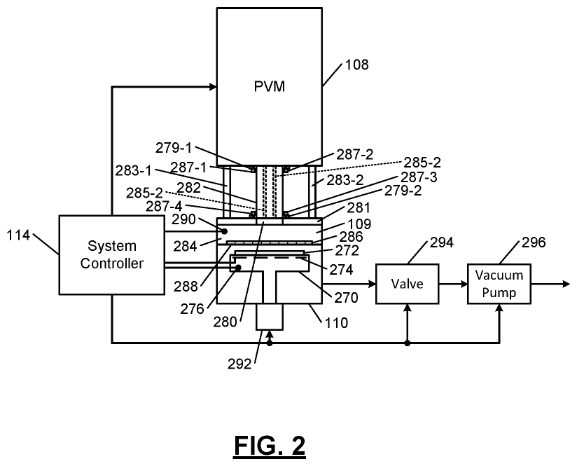

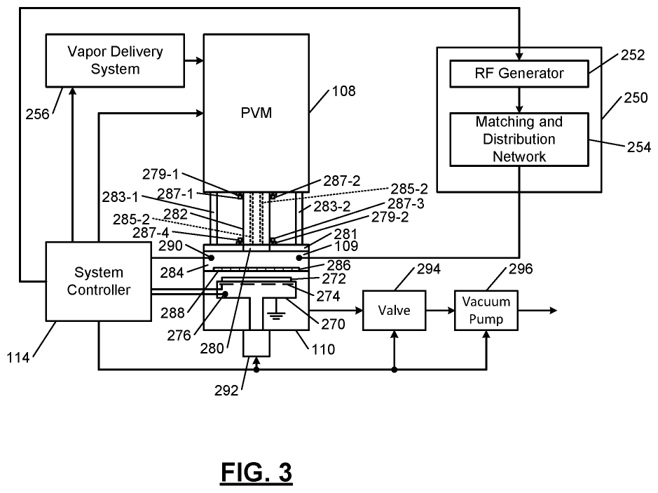

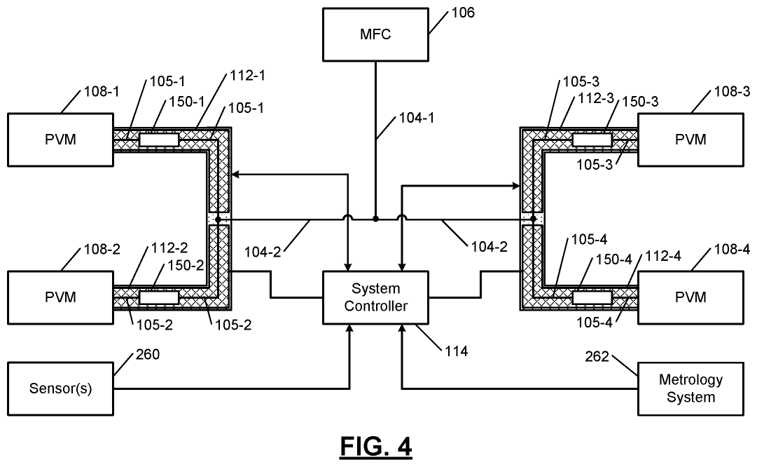

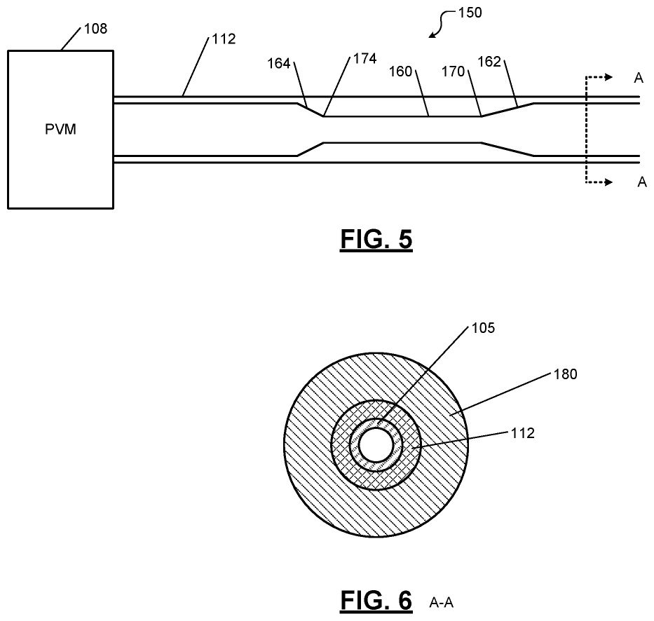

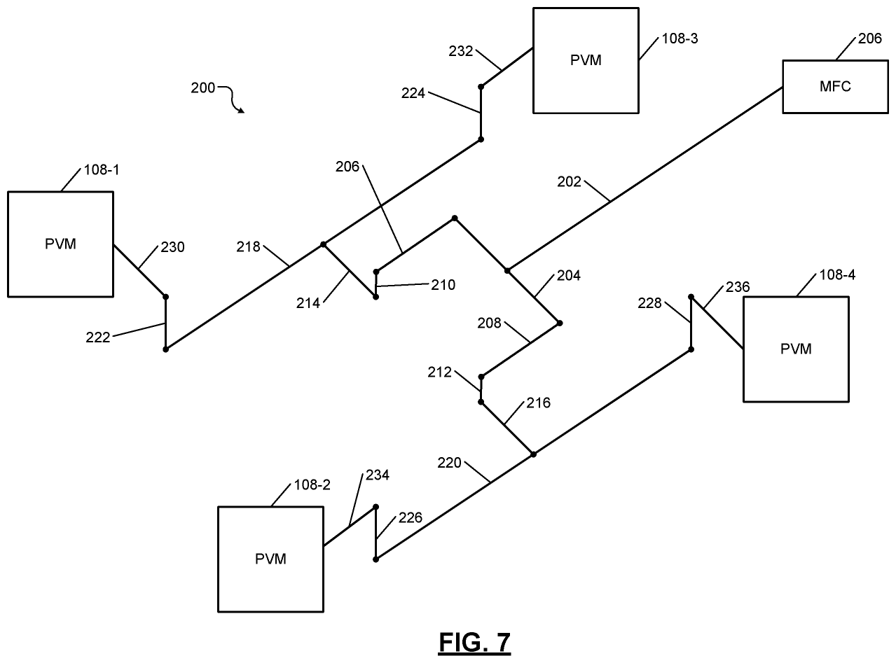

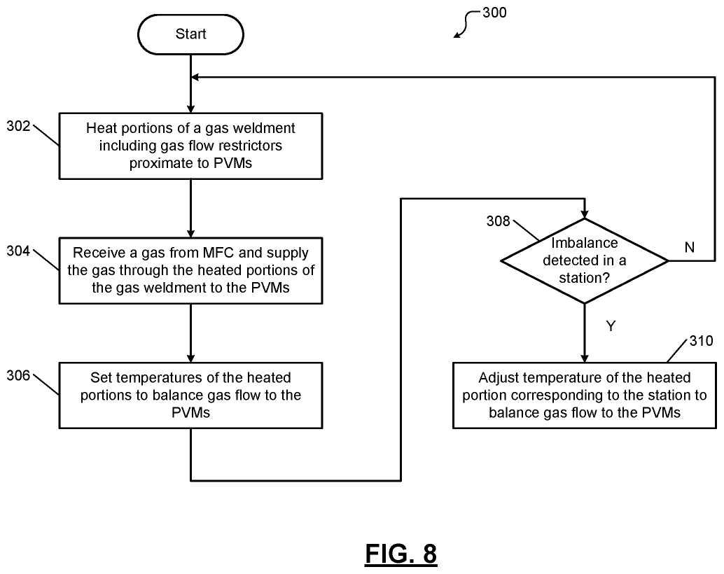

The present disclosure is organized as follows. An example of a substrate processing system (also called a tool) employing the heating system of the present disclosure is shown and described with reference to FIG. 1. Examples of stations (also called processing chambers or process modules) used in the tool of FIG. 1 are shown and described with reference to FIGS. 2 and 3. FIG. 2 shows an example of an atomic layer deposition (ALD) station, and FIG. 3 shows an example of a plasma enhanced chemical vapor deposition (PECVD) station. FIG. 4 shows an example of the heating system according to the present disclosure in detail. FIG. 5 shows an example of a gas flow restrictor used with the heating system of FIG. 4. FIG. 6 shows a cross-section of a gas weldment segment comprising a heater of the heating system. FIG. 7 schematically shows an example of a gas weldment divided and connected to PVMs of stations without using the heating system of the present disclosure. The purpose of FIG. 7 is to show how the gas weldment without the heaters typically comprises multiple portions that turn at right angles, which is unnecessary when the heating system is used as described below in detail. FIG. 8 shows a method of balancing gas flow to multiple stations using the heating system of the present disclosure.

FIG. 1 shows an example of a substrate processing system (hereinafter a tool) 100. The tool 100 comprises gas and precursor sources (hereinafter collectively called the gas sources) 102. In addition to precursors, non-limiting examples of the gases supplied by the gas sources 102 comprise reactants, inert gases, and other gases. The tool 100 comprises a mass flow controller (MFC) 106. The MFC 106 controls the flow of a gas supplied by the gas sources 102 through a gas weldment. The gas weldment comprises first and second portions (elements 104 and 105 described below). Only one MFC 106 is shown for simplicity of illustration. However, the tool 100 may comprise a plurality of MFCs that control the mass flow of the gases supplied by the gas sources 102 through the gas weldment. In some examples, multiple gas weldments may be used with respective MFCs. The following description of the gas weldment applies equally to these gas weldments.

The first portion 104 of the gas weldment extends from the MFC 106. The second portion of the gas weldment is divided into multiple segments (elements 105 described below). The first and second portions form the gas weldment. The first portion 104 comprises conduits 104-1 and 104-2. The conduit 104-1 extends from the MFC 106. A distal end of the conduit 104-1 is connected between two ends of the conduit 104-2. The second portion 105 is divided into segments 105-1, 105-2, 105-3, and 105-4 (collectively the segments 105). First ends of the segments 105 are connected to the conduit 104-2. Distal ends of the segments 105 are respectively connected to a plurality of PVMs 108-1, 108-2, 108-3, and 108-4 (collectively the PVMs 108). The first and second portions 104, 105 of the gas weldment are in fluid communication with each other. The first and second portions 104, 105 provide a continuous flow path for the gas from the MFC 106 to the PVMs 108.

The tool 100 comprises plurality of stations 110-1, 110-2, 110-3, and 110-4 (collectively the stations 110). The stations 110 respectively comprise showerheads 109-1, 109-2, 109-3, and 109-4 (collectively the showerheads 109). The PVMs 108 are respectively connected to showerheads 109. The PVMs 108 supply the gases supplied by the gas sources 102 to the respective stations 110. The PVMs 108 supply the gases to the stations 110 via the respective showerheads 109. The PVMs 108 supply the gases to the stations 110 at a predetermined temperature and pressure. Only four PVMs 108 and only four stations 110 are shown for example only. The tool 100 may comprise N PVMs 108 and N stations 110, where N is an integer greater than 2.

The segments 105 are heated by respective heaters 112-1, 112-2, 112-3, and 112-4 (collectively the heaters 112). The heaters 112 surround the respective segments 105. The heaters 112 are shown and described in detail with reference to FIG. 6. The gas weldment can be divided in other ways between the MFC 106 and the PVMs 108 than shown in this example. Another example of dividing the gas weldment between the MFC 106 and the PVMs 108 is shown and described below with reference to FIG. 4.

Regardless of how the gas weldment is divided, the segments 105 connect to the respective PVMs 108, and the segments 105 surround and are heated by respective heaters 112. The segments 105 also comprise respective gas flow restrictors proximate to the PVMs 108. An example of a gas flow restrictor is shown and described below with reference to FIG. 5. The gas from the segments 105 flows through the gas flow restrictors into the respective PVMs 108. The heaters 112 also surround the gas flow restrictors and extend to the PVMs 108.

Note that only the segments 105 are heated. The first portion 104 of the gas weldment comprising the conduits 104-1 and 104-2 is not heated. Heating only the segments 105 ensures efficiently heating the gas and balancing the gas flow close to the point of entry of the gas into the PVM 108. Heating the first portion 104 in addition to the segments 105 amounts to heating the entire gas weldment from the MFC 106 to the PVM 108. Heating the entire gas weldment is inefficient and can give rise to a thermal gradient across the first portion 104 and the segment 105. Due to the thermal gradient, heating the entire gas weldment cannot balance the gas flow close to the point of entry of the gas into the PVM 108. Therefore, the entire gas weldment is not heated. Instead, only portions of the gas weldment that are proximate to the PVM 108 and that comprise the gas flow restrictor 150 are heated.

The tool 100 further comprises a system controller 114. The system controller 114 controls the gas sources 102, the MFC 106, the heaters 112, components of the stations 110, and other elements of the tool 100. Examples of the components of the stations 110 and the other elements of the tool 100 are shown and described below with reference to FIGS. 2 and 3.

FIG. 2 shows an example of the station 110, which can be any of the stations 110 of the tool 100. For example, the station 110 can be an ALD station. That is, the station 110 can be used to perform an ALD process on a substrate in the station 110. Another example of the station 110 that can perform a PECVD process on a substrate is shown and described below with reference to FIG. 3. While ALD and PECVD processes are described as illustrative examples, other processes can be performed on substrates in the stations 110.

In FIG. 2, the station 110 is configured to process a substrate 272 using an ALD process (e.g., using thermal ALT or T-ALD). The station 110 comprises a substrate support (e.g., a pedestal) 270. During processing, the substrate 272 is arranged on the pedestal 270. One or more heaters 274 (e.g., a heater array, zone heaters, etc.) may be arranged in the pedestal 270 to heat the substrate 272 during processing. Additionally, one or more temperature sensors 276 are disposed in the pedestal 270 to sense the temperature of the pedestal 270. The system controller 114 receives the temperature of the pedestal 270 sensed by the temperature sensors 276. The system controller 114 controls power supplied to the heaters 274 based on the sensed temperature.

The station 110 further comprises the showerhead 109. The showerhead 109 introduces and distributes process gases received from the PVM 108 into the station 110. The showerhead 109 comprises a stem portion 280. One end of the stem portion 280 is connected to a top plate 281 enclosing the station 110. The PVM 108 is mounted to a top plate 281 above the showerhead 109 using at least two mounting legs 283-1, 283-2.

The PVM 108 is connected to the stem portion 280 of the showerhead 109 via an adapter 282. The adapter 282 comprises a first flange 279-1 on a first end and a second flange 279-2 on a second end of the adapter 282. The flanges 279-1, 279-2 are respectively fastened to the bottom of the PVM 108 and to the stem portion 280 of the showerhead 109 by fasteners 287-1 through 287-4. The adapter comprises bores 285-1, 285-2 (collectively the bores 285). The bores 285 are in fluid communication with the PVM 108 and the stem portion 280 of the showerhead 109. A base portion 284 of the showerhead 109 is generally cylindrical. The base portion 284 extends radially outwardly from an opposite end of the stem portion 280 at a location that is spaced from a top surface of the station 110.

A substrate-facing surface of the base portion 284 of the showerhead 109 comprises a faceplate 286. The faceplate 286 comprises a plurality of outlets or features (e.g., slots or through holes) 288. The outlets 288 of the faceplate 286 are in fluid communication with the PVM 108 through the bores 285 of the adapter 282. The process gases flow from the PVM 108 through the bores 285 and the outlets 288 into the station 110.

Additionally, while not shown, the showerhead 109 also comprises one or more heaters. The showerhead 109 comprises one or more temperature sensors 290 to sense the temperature of the showerhead 109. The system controller 114 receives the temperature of the showerhead 109 sensed by the temperature sensors 290. The system controller 114 controls power supplied to the one or more heaters in the showerhead 109 based on the sensed temperature.

An actuator 292 is operable to move the pedestal 270 vertically relative to the showerhead 109, which is stationary. By vertically moving the pedestal 270 relative to the showerhead 109, a gap between the showerhead 109 and the pedestal 270 (i.e., between the substrate 272 and the faceplate 286 of the showerhead 109) can be varied. The gap can be varied dynamically during a process or between processes performed on the substrate 272. During processing, the faceplate 286 of the showerhead 109 can be closer to the pedestal 270 than shown.

A valve 294 is connected to an exhaust port of the station 110 and to the vacuum pump 296. The vacuum pump 296 can maintain sub-atmospheric pressure inside the station 110 during substrate processing. The valve 294 and the vacuum pump 296 are used to control pressure in the station 110 and to evacuate exhaust gases and reactants from the station 110. The system controller 114 controls these additional components associated with the station 110.

FIG. 3 shows another example of the station 110 configured to perform a PECVD process on the substrate 272. All elements of FIG. 3 that are also shown in FIG. 2 with identical reference numerals are not described again for brevity. Additionally, to perform the PECVD process, the tool 100 may comprise a radio frequency (RF) generating system (or an RF source) 250. The RF generating system 250 generates and outputs an RF voltage. The RF voltage may be applied to the showerhead 109. The pedestal 270 can be direct current (DC) grounded, alternating current (AC) grounded, or floating as shown. Alternatively, while not shown, the RF voltage can be applied to the pedestal 270. The showerhead 109 may be DC grounded, AC grounded, or floating.

For example, the RF generating system 250 may comprise an RF generator 252. The RF generator 252 generates RF power. The RF power is fed by a matching and distribution network 254 to the showerhead 109 or the pedestal 270. In some examples, a vapor delivery system 256 supplies a vaporized precursor to the PVM 108. The RF voltage supplied to the showerhead 109 or the pedestal 270 strikes plasma in the station 110 to perform a PECVD process on the substrate 272. Alternatively, inductive plasma or plasma generated remotely from (i.e., external to) the station 110 may be used to perform the PECVD process.

FIG. 4 shows another example of the heating system comprising the heaters 112. In FIG. 4, the second portion of the gas weldment is divided into segments differently than in FIG. 1. For example, the second portion of the gas weldment is subdivided into two sections. Each section is further divided into two segments. For example, a first section of the second portion of the gas weldment is divided into the segments 105-1, 105-2. A second section of the second portion of the gas weldment is divided into the segments 105-3, 105-4.

Alternatively, the gas weldment can be divided into segments in other ways. For example, instead of dividing the gas weldment into first and second portions and then subdividing the second portion into segments as shown in FIG. 1 or 4, the gas weldment may comprise four separate conduits. The four separate conduits may extend from the MFC 106 directly to the respective PVM 108 independently of each other. In such a configuration, each of the conduits comprises a gas flow restrictor at distal ends of the conduits proximate to the PVMs 108. Further, portions of the conduits proximate to the PVMs 108, comprising the gas flow restrictors, are heated by the heaters 112.

In FIG. 4, the segments 105-1, 105-2 respectively comprise gas flow restrictors 150-1, 150-2. The segments 105-3, 105-4 respectively comprise gas flow restrictors 150-3, 150-4. The heaters 112-1, 112-2 respectively heat the segments 105-1, 105-2 that comprise the respective gas flow restrictors 150-1, 150-2. The heaters 112-3, 112-4 respectively heat the segments 105-3, 105-3 that comprise the respective gas flow restrictors 150-3, 150-4. The gas flow restrictors 150-1, 150-2, 150-3, and 150-4 are collectively called the gas flow restrictors 150. The gas flow restrictors 150 are not shown in FIG. 1 to simplify illustration of the other elements of the tool 100. However, the segments 105 in FIG. 1 also comprise the gas flow restrictors 150 proximate to the PVMs 108.

The structure of the gas flow restrictors 150 is shown and described with reference to FIG. 5. The structure of the heaters 112 is shown and described with reference to FIG. 6. The functions performed by the gas flow restrictors 150 and the heaters 112 are described below with reference to FIG. 4.

In FIG. 4, each gas flow restrictor 150 supplies the gas from the respective segment 105 to the respective PVM 108 at a constant pressure. The MFC 106 controls the pressure at which the gas is supplied through the first and second portions 104, 105 of the gas weldment. The gas flow restrictor 150 prevents any temperature variations that may occur downstream from affecting gas flow upstream in the gas weldment. For example, the temperature variations may occur in the PVM 108, the showerhead 109, and/or the station 110.

However, the gas flow in the gas weldment upstream from the gas flow restrictor 150 can be affected by factors comprising but not limited to temperature changes that may occur in regions surrounding the gas weldment. For example, such temperature changes may occur due to heat conducted by the top plate 281. Such temperature changes may occur due to temperature variations in other elements of the tool proximate to the gas weldment, etc. These temperature changes in the regions surrounding the gas weldment change the pressure at which the gas flows through the gas weldment. The gas flow restrictor 150 alone is insufficient to compensate these pressure changes that may occur upstream from the gas flow restrictor 150 in the gas weldment. These pressure changes can be prevented by heating only the segments 105 of the gas weldment using the heaters 112 as follows.

The system controller 114 individually controls the heaters 112 to control the temperatures of the segments 105 of the gas weldment independently of each other. By individually controlling the heaters 112, the pressure at which the gas flows through the segments 105 of the gas weldment into the respective PVMs 108 is individually controlled. Consequently, the mass flow of the gas supplied to each gas flow restrictor 150 and to the respective PVMs 108 is uniform. Accordingly, the gas flow restrictor 150 can supply the gas from the MFC 106 to each PVM 108 (and ultimately to the stations 110) with uniform (i.e., matched) mass flow. Thus, using the combination of the gas flow restrictors 150 and the heaters 112, the gas is supplied from the MFC 106 to each PMV 108 and the station 110 at a constant mass flow.

Typically, when the stations 110 perform the same process on the substrates, station-to-station process non-uniformities may occur. For example, the station-to-station process non-uniformities comprise variations in depositions performed on the substrates in one station relative to another. The non-uniformities may occur due to flow imbalance caused by factors such as manufacturing tolerances in the gas weldment, temperature variations in the regions surrounding the gas weldment, etc. According to the present disclosure, the flow balancing is performed by the combination of the gas flow restrictors 150 and heating the segments 105 and the gas flow restrictors 150. Therefore, when the stations 110 perform the same process on the substrates, the non-uniformities are significantly reduced as compared to when the segments 105 and the gas flow restrictors 150 are not heated.

As described above, the temperature setpoints of each of the heaters 112 for a process to be performed in the stations 110 can be calibrated (e.g., set empirically). The temperature setpoints can be calibrated during the manufacturing of the tool 100 and/or at the time of setting up the tool 100 on site. That is, based on requirements of a process to be performed on the substrate 272 in the stations 110, the amount of power supplied by the system controller 114 to each of the heaters 112 can be adjusted. The adjustments compensate for any variations in the manufacturing tolerances that may inevitably occur in the manufacture of the conduits used to form the gas weldment. Due to the adjustments, the gas from the MFC 106 is supplied with uniform mass flow from the MFC 106 to each of the PVMs 108 and the stations 110. The gas is supplied with uniform mass flow regardless of the variations in the manufacturing tolerances.

Further, the temperature setpoints can be re-calibrated during preventive maintenance of the tool 100 as needed. Furthermore, the temperature setpoints can be adjusted during runtime (i.e., while the process is running). For example, the system controller 114 may receive feedback from a pressure sensor in the PVM 108. The system controller 114 may receive feedback from other sensors in the station 110 and/or in the tool 100. These sensors are collectively shown as sensors at 260. The feedback from the sensors 260 may be indicative of non-uniformities in the substrate 272 that may occur in one station but not in other stations. The system controller 114 can adjust the temperature setpoint for the heater 112 of the segment 105 associates with that station 110 based on the feedback from the sensors 260. While not shown in FIG. 1 to simplify illustration of the other elements of the tool 100, the system controller 114 shown in FIG. 1 also communicates with the sensors 260.

Alternatively or additionally, the system controller 114 may receive data from an in-situ (or external) metrology system 262 as feedback. For example, the metrology system 262 may measure a property of the substrate 272 processed in a station. For example, the metrology system 262 may measure thickness of a film deposited on the substrate 272 by a process in a station. The data from the metrology system 262 may indicate variation in the substrate 272 processed using a process in one station compared to the substrate 272 processed using the same process in another station. Based on the data from the metrology system 262, the system controller 114 can adjust the temperature setpoint for the heater 112 of the segment 105 that associated with the station 110 in which the property of the substrate 272 indicates a variation. The variation may occur although the same process is used to process the substrate 27 in each of the stations 110. While not shown in FIG. 1 to simplify illustration of the other elements of the tool 100, the system controller 114 shown in FIG. 1 also communicates with the metrology system 262.

Again, only the segments 105 are heated. The first portion 104 of the gas weldment comprising the conduits 104-1 and 104-2 is not heated. Heating only the segments 105 ensures efficiently heating the gas and balancing the gas flow close to the point of entry of the gas into the PVM 108. Heating the first portion 104 in addition to the segments 105 amounts to heating the entire gas weldment from the MFC 106 to the PVM 108. Heating the entire gas weldment is inefficient and can give rise to a thermal gradient across the first portion 104 and the segment 105. Due to the thermal gradient, heating the entire gas weldment cannot balance the gas flow close to the point of entry of the gas into the PVM 108. Therefore, the entire gas weldment is not heated. Instead, only portions of the gas weldment that are proximate to the PVM 108 and that comprise the gas flow restrictor 150 are heated.

FIG. 5 shows the structure of the gas flow restrictor 150. The heater 112 is not shown in detail to focus on the structure of the gas flow restrictor 150. FIG. 6, which shows a cross-section of the segment 105 taken along line A-A shown in FIG. 5, shows the heater 112 in detail.

In FIG. 5, the gas flow restrictor 150 is located near a distal end of the segment 105 connected to the PVM 108. The gas flow restrictor 150 comprises three elements: a first element 160, a second element 162, and a third element 164. The second element 162 is connected to a first end 170 of the first element 160. The third element 164 is connected to a second end 174 of the first element 160. The first element 160 has a smaller cross-section than the segment 105. For example, if the segment 105 is circular, the first element 160 has a smaller diameter than the segment 105. The first element 160 has a predetermined length that is less than the length of the segment 105.

The second element 162 tapers radially inwardly from the segment 105 towards the first end 170 of the first element 160. A tapered end of the second element 162 connects to the first end 170 of the first element 160. The pressure of the gas increases as the gas flows from the segment 105 through the second element 162 into the first element 160. The gas exits a tapered end of the second element 162 and enters into the first end 170 of the first element 160 at a higher pressure than the pressure at which the gas enters into a non-tapered end of the second element 162. Stated differently, the gas exits the second element 162 at a higher pressure than the pressure at which the gas flows through the segment 105. The gas flows through the first element 160 at the higher pressure.

The third element 164 flares radially outwardly from the second end 174 of the first element 160. A flared end of the third element 164 connects to the distal end of the segment 105 proximate to the PVM 108. The pressure of the gas decreases as the gas flows from the second end 174 of the first element 160 through the third element 164 into the distal end of the segment 105. The gas exits the second end 174 of the first element 160 at the higher pressure. The gas exits the flared end of the third element 164 and enters into the distal end of the segment 105 at a lower pressure than the pressure at which the gas exits the second end 174 of the first element 160. Stated differently, the gas exits the third element 164 at a lower pressure than the pressure at which the gas flows through the first element 160. The gas flows through the distal end of the segment 105 into the PVM 108 at the lower pressure.

FIG. 6 shows a cross-section of the segment 105 taken along the line A-A shown in FIG. 5. The heater 112 (e.g., a heater coil) is arranged coaxially around the segment 105. The segment 105 conducts the heat supplied by the heater 112 to the gas flowing through the segment 105, the gas flow restrictor 150, and the distal end of the segment 105 connected to the PVM 108. A layer of thermal insulation 180 is arranged coaxially around the heater 112. The layer of thermal insulation 180 prevents changes in temperature in the regions surrounding the segment 105 from affecting the temperature of the segment 105.

FIG. 7 shows an example layout of a gas weldment 200 without using the heaters 112. For example, the gas weldment 200 comprises a plurality of conduits interconnected as follow. The arrangement of the conduits depends on the arrangements of other components arranged on the top plate of the tool.

In one example, a first conduit 202 extends from the MFC 106. A first end of the first conduit 202 is connected to the MFC 106. A second conduit 204 is substantially perpendicular to the first conduit 202. A second end of the first conduit 202 is connected between two ends (e.g., at a center) of the second conduit 204. Third and fourth conduits 206, 208 extend substantially perpendicularly from the two ends of the second conduit 204. The first, third, and fourth conduits 202, 206, 208 are substantially parallel to each other. The first, second, third, and fourth conduits 202, 204, 206, 208 are substantially coplanar and lie in a first plane.

Fifth and sixth conduits 210, 212 respectively extend substantially perpendicularly downwards from distal ends of the third and fourth conduits 206, 208. The fifth and sixth conduits 210, 212 are substantially parallel to each other. Seventh and eighth conduits 214, 216 respectively extend substantially perpendicularly from distal ends of the fifth and sixth conduits 210, 212.

Ninth and tenth conduits 218, 220 extend substantially perpendicularly from distal ends of the seventh and eighth conduits 214, 216, respectively. The ninth and tenth conduits 218, 220 are substantially parallel to each other and to the first, third, and fourth conduits 202, 206, 208. The distal ends of the seventh and eighth conduits 214, 216 are respectively connected between two ends (e.g., at a center) of the ninth and tenth conduits 218, 220. The seventh, eighth, ninth, and tenth conduits 214, 216, 218, 220 are substantially coplanar and lie in a second plane. The first and second planes are substantially parallel to each other.

Eleventh and twelfth conduits 222, 224 respectively extend substantially perpendicularly upwards from the two ends of the ninth conduit 218. Thirteenth and fourteenth conduits 226, 228 respectively extend substantially perpendicularly upwards from the two ends of the tenth conduit 220. The eleventh, twelfth, thirteenth, and fourteenth conduits 222, 224, 226, 228 are substantially parallel to each other and to the fifth and sixth conduits 206, 208.

Fifteenth and sixteenth conduits 230, 232 respectively extend substantially perpendicularly from distal ends of the eleventh and twelfth conduits 222, 224. Seventeenth and eighteenth conduits 234, 236 respectively extend substantially perpendicularly from distal ends of the thirteenth and fourteenth conduits 226, 228. Distal ends of the fifteenth, sixteenth, seventeenth, and eighteenth conduits 230, 232, 234, 236 connect to the respective PVMs 108. The fifteenth, sixteenth, seventeenth, and eighteenth conduits 230, 232, 234, 236 are substantially coplanar and may lie in the first plane or a third plane that may be parallel to the first and/or the second plane.

Note that the joints of these conduits, except the joints of the first and second conduits 202, 204; the seventh and ninth conduits 214, 218; and the eighth and tenth conduits 216, 220 are substantially at right angles. The right angled joints of these conduits help maintain a constant pressure in the gas weldment 200, but only to a limited extent. Further, the gas weldment 200 requires assembling (i.e., arranging and joining) of these various and numerous conduits in the above manner. Multiple conduits are helpful in routing and arranging the conduits between and around the various components of the tool arranged on the top plate. However, the numerous conduits can have different manufacturing tolerances, which can adversely affect the mass flow of the gas in the gas weldment 200.

With the addition of the heaters 212 on the segments 105 as described above, the variations in the manufacturing tolerances of these conduits can be compensated. Further, the number of conduits can be significantly reduced. For example, the second through eighth conduits 204-216 can be replaced by a single conduit. The ninth, eleventh, twelfth, fifteenth, and sixteenth conduits 218, 222, 224, 230, 232 can be replaced by a single conduit. The tenth, thirteenth, fourteenth, seventeenth, and eighteenth conduits 220, 226, 228, 234, 236 can be replaced by a single conduit. The number of conduits can be reduced by combining the conduits in other ways.

Furthermore, the single conduits formed by combining different conduits can be of any shape. The single conduits eliminate the need to join multiple conduits at right angles. Additionally, since the single conduits can be of any shape, the single conduits can also be routed and arranged between and around the various components of the tool arranged on the top plate. Accordingly, the single conduits not only reduce the total number of conduits in the gas weldment but also provide flexibility in routing and arranging them between and around the various components of the tool arranged on the top plate. Due to fewer number of conduits in such a configuration, the variations due to manufacturing tolerances are also reduced. By using the heaters 112, the gas weldment obviates the need for the right angled turns and provides better mass flow control than when the right angled turns are used at the joints of the conduits.

FIG. 8 shows a method 300 for balancing gas flow to multiple stations using the heating system of the present disclosure. For example, the system controller 114 performs the method 300. At 302, the method 300 heats portions of a gas weldment (i.e., a plurality of interconnected conduits) that comprise gas flow restrictors and that are proximate to PVMs. At 304, the method 300 receives a gas from a mass flow controller via an inlet of the gas weldment and supplies the gas to the PVMs through the heated portions of the gas weldment. At 306, the method 300 sets temperatures of the heated portions (i.e., sets power supplied to heaters used to heat the portions) to balance the gas flow to the PVMs.

At 308, the method determines if gas flow to one of the PVMs is imbalanced. The method 300 returns to 302 if gas flow to one of the PVMs is not imbalanced (i.e., if the gas to all the PVMs is balanced). If gas flow to one of the PVMs is imbalanced, at 310, the method 300 adjusts the temperature (i.e., adjusts the power supplied to a heater associated with the portion of the gas weldment supplying the gas to the one of the PVMs to which the gas flow is imbalanced) to rebalance the gas flow to the PVMs.

The foregoing description is merely illustrative in nature and is not intended to limit the disclosure, its application, or uses. The broad teachings of the disclosure can be implemented in a variety of forms. Therefore, while this disclosure comprises particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as comprising certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, comprising “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, comprising a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, comprising the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics comprising various integrated circuits, logic, memory, and/or software that receive instructions, issue instructions, control operation, enable cleaning operations, enable endpoint measurements, and the like. The integrated circuits may comprise chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may comprise a local network or the Internet. The remote computer may comprise a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may comprise a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A system for supplying a gas to a plurality of stations of a substrate processing tool, the system comprising:
a gas source configured to supply the gas;
a mass flow controller connected to the gas source;
a plurality of conduits interconnected to each other and in fluid communication with each other, wherein the plurality of conduits comprises:
an inlet connected to the mass flow controller;
a plurality of portions comprising a plurality of outlets, respectively;
wherein the plurality of outlets are connected to a plurality of manifolds, respectively; and
wherein the plurality of manifolds are configured to supply the gas to the plurality of stations of the substrate processing tool, respectively; and
a plurality of gas flow restrictors arranged in the plurality of portions, respectively; wherein the plurality of gas flow restrictors are arranged proximate to the plurality of outlets, respectively; and
a plurality of heaters coupled to the plurality of portions, respectively;
wherein the plurality of heaters are arranged proximate to the plurality of outlets, respectively; and
wherein the plurality of heaters are configured to heat the plurality of portions comprising the plurality of gas flow restrictors, respectively.

2. The system of claim 1, wherein the plurality of heaters is arranged coaxially around the plurality of portions of the plurality of conduits, respectively.

3. The system of claim 1, wherein the plurality of heaters surround the plurality of portions of the plurality of conduits, respectively.

4. The system of claim 1, wherein the plurality of heaters extend to the plurality of outlets, respectively.

5. The system of claim 1, wherein inner portions of the plurality of heaters are adjacent to and in thermal communication with the plurality of portions of the plurality of conduits and wherein outer portions of the plurality of heaters comprise a layer of a thermally insulating material.

6. The system of claim 1, further comprising a controller to supply power to the plurality of heaters to balance flow of the gas through the plurality of outlets.

7. The system of claim 6, wherein the controller is configured to control the power supplied to each of the plurality of heaters to balance the flow of the gas through the plurality of outlets.

8. The system of claim 6, wherein the controller is configured to adjust the power supplied to at least one of the plurality of heaters in response to the flow of the gas through one of the plurality of outlets being different than the flow of the gas through others of the plurality of outlets.

9. The system of claim 6, wherein the controller is configured to:
receive data from a component of the substrate processing tool located downstream of one of the outlets, wherein the data is indicative of the flow of the gas through one of the plurality of outlets being different than the flow of the gas through others of the plurality of outlets; and
adjust the power supplied to at least one of the plurality of heaters based on the data to balance the flow of the gas through the plurality of outlets.

10. The system of claim 9, wherein the component comprises a sensor associated with one of the stations receiving the gas from the one of the plurality of outlets.

11. The system of claim 9, wherein the component comprises a metrology system.

12. The system of claim 1, wherein at least two of the plurality of conduits are interconnected at an angle other than a right angle.

13. A method for balancing gas flow to a plurality of stations of a substrate processing tool, the method comprising:
receiving a gas from a gas source;
interconnecting a plurality of conduits to comprise:
an inlet to receive the gas; and
a plurality of outlets in a plurality of portions of the plurality of conduits, respectively;
controlling the gas flow through the plurality of conduits using a mass flow controller connected to the inlet;
restricting the gas flow through the plurality of portions of the plurality of conduits proximate to the plurality of outlets;
heating the plurality of portions of the plurality of conduits proximate to the plurality of outlets;
balancing the gas flow through the plurality of outlets based on the restricting and the heating; and
supplying the gas from the plurality of outlets through a plurality of manifolds, the plurality of manifolds being connected to the plurality of outlets, respectively, and to the plurality of stations of the substrate processing tool, respectively.

14. The method of claim 13, further comprising thermally insulating the heated portions of the plurality of conduits.

15. The method of claim 13, further comprising adjusting the heating of one of the plurality of portions in response to the gas flow through one of the plurality of outlets associated with the one of the plurality of portions being different than the gas flow through others of the plurality of outlets.

16. The method of claim 13, further comprising controlling the heating of the plurality of portions based on data received from a component of the substrate processing tool located downstream of one of the outlets to balance the gas flow through the plurality of outlets.

17. The method of claim 13, further comprising controlling the heating of the plurality of portions based on data received from a metrology system to balance the gas flow through the plurality of outlets.

18. The method of claim 13, further comprising interconnecting at least two of the plurality of conduits at an angle other than a right angle.
